(19) United States
(12) Patent Application Publication
(10) Pub. No.: US 2009/0007950 A1
(43) Pub. Date: Jan. 8, 2009

(54) LONGITUDINAL QUANTUM HEAT CONVERTER

(76) Inventors: Eliade Stefanescu, Bucharest (RO); Lucien Eugene Cornescu, Bucharest 2 (RO)

Correspondence Address: GRIFFIN & SZIPL, PC, SUITE PH-1, 2300 NINTH STREET, SOUTH, ARLINGTON, VA, 22204, US

(21) Appl. No.: 11/773,793

(22) Filed: Jul. 5, 2007

(51) Int. Cl. H01L 35/00; H01L 31/0352; H01S 5/32

(52) U.S. Cl. 136/201; 136/205; 257/21; 372/1; 257/E31.033

(57) ABSTRACT

A method for the environment heat conversion in coherent electromagnetic energy by a super radiant quantum decay and a thermal excitation of a system of electrons is disclosed. A semiconductor device is also disclosed comprising a system of n-i-p-n transistors, a double array of quantum dots on the two sides of the thin i-layer of the n-i emitter, a system of intermediate n and p layers separating the active quantum region from the n and respectively p regions by potential barriers, a metal front electrode, a heat absorber in intimate contact with this electrode, a semitransparent rear electrode forming with the front electrode a Fabry-Perot resonator tuned with the electron quantum transition frequency through the i-layer, and an output semitransparent mirror of the same transparency as the transparency of the rear electrode, by this forming with the rear electrode a total transmission Fabry-Perot resonator.

### FIELD OF INVENTION

The present invention generally concerns a quantum heat converter for producing coherent electromagnetic energy on the account of the environmental heat. More particularly, the invention refers to a method and a quantum device converting heat in usable coherent electromagnetic energy by super radiant transitions supplied by an injection of electrons.

### BACKGROUND OF THE INVENTION

First of all, if one considers the growing needs nowadays for new sources of energy and more especially of clean and renewable energies, as well as cooling issues for the planet, new solutions have to be developed. Many efforts have been recently done in connection with energies such as solar radiation, hydraulic power of tides or wind, etc. Nevertheless, all these energies require huge installations such as fields of solar panels or wind turbines or hydroelectric power stations and long distribution networks. Furthermore, the amount of energy produced is very low in comparison to the efforts and means needed.

There is the well-known prior art method for converting the solar radiation in electric power by the absorption of this radiation in the internal field of a semiconductor p-i-n junction that separates the generated electric charges as described for example in the prior publication U.S. Pat. No. 4,765,845. The devices built on the basis of this method, usually named solar cells, are semiconductor p-i-n diodes with a system of electrodes optimizing the radiation penetration in the semiconductor volume and the charge collection from this volume. However, the efficiency of this method is rather low, especially for three main reasons: (1) only a narrow part of the incident radiation spectrum is converted into energy, this conversion being based on a quasi-resonant effect of transitions between the margins of the conduction bands stimulated by light, (2) the efficient absorption region, that is restricted to the internal field zone of a semiconductor junction, is rather narrow, an important part of the incident field being lost in the neighbouring neutral zones of the device that do not produce any conversion of radiation into electric power, and (3) the excited charges, electrons and holes coexisting in the same semiconductor region, have large wave-function overlaps, leading to strong dissipative couplings between the charge carriers, and between these carriers and the crystal lattice.

Alternative solutions based on quantum phenomena for producing energy are currently considered. The approach is based on a quantum theory of open systems, taking into account the energy exchange between a system of fermions and its environment in full agreement with the quantum mechanical and detailed balance conditions detailed in the prior publication in the name of E. Stefanescu, entitled “Dynamics of Fermi system with tunnelling dissipation and dynamical detailed balance” in Physica A 350 (2005, pages 227-244), which is enclosed herewith by way of reference.

The dynamics of such a system interacting with an environment of other fermions, bosons and the free electromagnetic field is described by the quantum master equation:

$$\frac{d}{d t} ρ ( t ) = - \frac{i}{ℏ} [ H , ρ ( t ) ] + {\sum }_{i , j = 1}^{N} {λ}_{ij} ( \begin{matrix}[ {c}_{i}^{+} {c}_{j} ρ ( t ) , {c}_{j}^{+} {c}_{i} ] + \\ [ {c}_{i}^{+} {c}_{j} , ρ ( t ) {c}_{j}^{+} {c}_{i} ]\end{matrix} ) \qquad ( 1 )$$

with the Hamiltonian of the dissipative system

H=Σᵢεᵢcᵢ⁺cᵢ (2)

and the N²−1 explicit dissipation coefficients for an N-level system of the form:

λᵢⱼ=λᵢⱼ^{F}+λᵢⱼ^{B}+γᵢⱼ. (3)

These coefficients depend on the dissipative two-body potentials V^{F} and V^{B} of interaction with the environment fermions and respectively bosons, the densities of the environment states g_{α}^{F}, g_{α}^{B} of environment fermions and respectively bosons, and the occupation probabilities of these states f_{α}^{F}, f_{α}^{B} depending on temperature T in the agreement with the detailed balance principle exposed in the abovementioned publication “Dynamics of Fermi system with tunnelling dissipation and dynamical detailed balance”. For a rather low temperature, T<<εⱼᵢ where j>i, the dissipative coefficients are of the form:

$$\begin{matrix}{λ}_{ij}^{F} = \frac{π}{ℏ} {\vert 〈 α i \vert {V}^{F} \vert {β}_{j} 〉 \vert}^{2} [ 1 - {f}_{α}^{F} ( {ɛ}_{ji} ) ] {g}_{α}^{F} ( {ɛ}_{ji} ) \\ {λ}_{ji}^{F} = \frac{π}{ℏ} {\vert 〈 α i \vert {V}^{F} \vert β j 〉 \vert}^{2} {f}_{α}^{F} ( {ɛ}_{ji} ) {g}_{α}^{F} ( {ɛ}_{ji} ) ,\end{matrix} \vert \qquad \begin{matrix}( 4 a ) \\ ( 4 b )\end{matrix}$$

for the Fermi environment,

$$\begin{matrix}{λ}_{ij}^{B} = \frac{π}{ℏ} {\vert 〈 α i \vert {V}^{B} \vert {β}_{j} 〉 \vert}^{2} [ 1 + {f}_{α}^{B} ( {ɛ}_{ji} ) ] {g}_{α}^{B} ( {ɛ}_{ji} ) \\ {λ}_{ji}^{B} = \frac{π}{ℏ} {\vert 〈 α i \vert {V}^{B} \vert β j 〉 \vert}^{2} {f}_{α}^{B} ( {ɛ}_{ji} ) {g}_{α}^{B} ( {ɛ}_{ji} )\end{matrix} \vert \qquad \begin{matrix}( 5 a ) \\ ( 5 b )\end{matrix}$$

for the Bose environment, and

$${γ}_{ij} = \frac{2 α}{{c}^{2} {ℏ}^{3}} {r}_{ij}^{- 2} {ɛ}_{ji}^{3} ( 1 + \frac{1}{{e}^{{ɛ}_{ji} / T} - 1} ) \vert \qquad ( 6 )$$

for the free electromagnetic field, where \vec{r}ᵢⱼ is the dipole moment and

$$α = \frac{{e}^{2}}{4 πɛ h c} \approx \frac{1}{137} \vert .$$

In this framework, the problem of converting the environment heat into coherent usable energy has been considered, taking into account the complete set of characteristics of the active system and of a complex dissipative environment. On this basis, a semiconductor device for converting a heat flow into super radiant power has been proposed in a prior publication, also enclosed herewith by way of reference, in the name of E. Stefabescu and W. Scheid, entitled “Superradiant dissipative tunnelling in a double p-i-n semiconductor heterostructure with thermal injection of electrons” in Physica A 374 (2007, pages 203-210).

The operation of this device is essentially based on the quantum nature of the active system. In a classical system, a usable kinetic energy can be obtained by decay from a higher potential to a lower one as, for instance, is the case of the water decay in a hydroelectric plant represented in FIGS. 1a and 1b. In this case, the kinetic energy Eₖ results from the difference between the initial potential energy U and the final potential energy U₀, minus an always present energy loss U_{L}. The energy Eₖ obtained from a flow between two potential energies U and U₀ is the same, no matter that this flow is a monotonic one with three steps 1-2-3 as represented in FIG. 1a, or has a much lower intermediate potential value U₁ with five steps 1-2-3-4-5 as showed in FIG. 1b.

### SUMMARY OF THE INVENTION

The main goal of the invention is to provide a new system for producing clean and renewable energy which avoids afore cited drawbacks of the prior art solutions. According to the present invention, a much more efficient quantum effect is carried out converting environment heat into usable coherent electromagnetic energy or electric energy.

For that purpose the invention concerns a method for producing in a semiconductor device coherent electromagnetic energy on the account of the environmental heat by an electron flow between an initial potential and a lower final potential, comprising two steps:

(i) a super radiant quantum decay of electrons to an intermediate potential that is lower than both the initial and the final potentials, and
(ii) a thermal excitation of electrons from the intermediate potential to the final potential by taking energy from an internal field region of the semiconductor device recovering this energy by heat absorption from the environment.

Thus, a somehow similar method for producing energy as the one presented in FIG. 1b is implemented, but of a quantum nature, where an electron decay from an initial energy level to an intermediate energy level is coupled with a super radiant mode of the electromagnetic field, while the excitation from the intermediate energy level to the final one is provided by heat absorption in an internal field region. In this way, the radiated power, corresponding to the decay from the initial energy level to the intermediate energy level, is much larger than the absorbed electric power, the difference being provided by heat absorption.

According to another aspect, the invention concerns a longitudinal quantum heat converter for environmental heat conversion into coherent electromagnetic energy, comprising at least one n-i-p-n structure with quantum dots on both sides of the i-layer, a metal front electrode and a rear electrode, both electrodes forming an active cavity with the n-i-p-n structure in-between, a heat absorber in thermal contact with the metal front electrode, and an external mirror defining a transmission output cavity with the rear electrode.

According to an advantageous variant, the n-i-p-n structure with quantum dots forms a super radiant transistor, the p-region being much narrower than the electron diffusion length, thus enabling the diffusion of these electrons from the n-i emitter region mainly to the collector p-n internal field region.

According to an advantageous variant, the first n and the p regions of the n-i-p-n structure form two conduction regions, and quantum dots together with the i-layer form an active quantum dot region which is separated from the two conduction regions by potential barriers, to diminish the dissipative coupling of the active electrons with the electrons in the conduction regions.

According to an advantageous variant, the potential barriers have rather high penetrability to enable quantum tunnelling between the active quantum dot region and the conduction regions.

According to an advantageous variant, the active cavity comprises several n-i-p-n structures connected in series so that there is an accumulation of super radiant transitions. Furthermore, such series of longitudinal quantum heat converters have the advantage of presenting an increased absorption power of the environmental heat.

According to another aspect, the invention concerns a semiconductor device for producing a coherent electromagnetic energy on the account of the environmental heat, comprising at least one n-i-p-n structure including an active electron system separated by potential barriers from a sea of conduction electrons, a heat absorber to supply the necessary thermal energy to the active electron system, and an output Fabry-Perot cavity with total transmission for extracting the coherent electromagnetic energy from the n-i-p-n structure.

According to another aspect, the invention concerns a longitudinal quantum heat converter for environmental heat conversion into coherent electromagnetic energy, comprising at least one n-i-p-n structure including a first n-i-p junction and a second p-n junction, a heat absorber in thermal contact with a metal front electrode of the n-i-p-n structure, and an external mirror defining a total transmission output cavity with a rear electrode of the n-i-p-n structure.

According to an advantageous variant, electrons crossing the first n-i-p junction by super radiant quantum decay, are injected by transistor effect in the second p-n junction.

According to another aspect, the invention concerns a longitudinal quantum heat converter for environmental heat conversion into coherent electromagnetic energy, comprising an active cavity with at least one n-i-p-n structure inside, a heat absorber in thermal contact with the active cavity, and a transmission output cavity for extracting electromagnetic energy from the active cavity.

According to another aspect, the invention concerns a quantum heat converter with thermal injection of electrons composed of two longitudinal quantum heat converters, electrically connected in ring, where one of the two longitudinal quantum heat converters is the load of the other and conversely, and optically paralleled, with the two n-emitters in thermal contact with a common heat absorber at a higher temperature and the two n-collectors in thermal contact with a heat radiator at a lower temperature, emitting two parallel electromagnetic beams by heat absorption from the environment. Such a solution is particularly adapted for environment which presents two different environmental temperatures. For instance, it may happen when the converter, or any of its possible support, is used in the cosmos, i.e. space, where one side will be exposed to the sun and the opposite side will remain in the dark. It may also happen when the converter or any of its possible support is placed in between two different middles, for example one side being in the air while the opposite side is immerged in water. The invention also concerns a similar converter with n>2 longitudinal quantum heat converters electrically connected in a ring, the total thermally generated voltage in this ring being equal to the voltage generated in one converter multiplied by the number of these converters.

According to another aspect, the invention concerns a quantum heat converter with auto injection for environmental heat conversion into coherent electromagnetic energy, comprising one longitudinal quantum heat converter, optically and electrically coupled with a quantum injection system wherein the coherent electromagnetic energy is partially used for generating injection current that is necessary to the operation of the longitudinal quantum heat converter.

According to another aspect, the invention concerns a quantum photo-electric converter for converting a coherent electromagnetic energy into electric energy by quasi-resonant transitions between bound quantum states, comprising at least one p-i-n structure with quantum dots on each side of the i-layer defining a quantum dot region, and potential barriers to separate this quantum dot region from the conduction p and n regions.

According to another aspect, the invention concerns a method for converting the environmental heat into electric energy in two steps: (1) a conversion of heat into coherent electromagnetic energy by a longitudinal quantum heat converter with auto injection, and (2) a conversion of a coherent electromagnetic energy into electric energy by a quantum photo-electric converter.

According to another aspect, the invention concerns a quantum thermoelectric converter for the environmental heat into electric energy comprising a longitudinal quantum heat converter with auto injection, and a quantum photo-electric converter for converting a coherent electromagnetic energy into electric energy by quasi-resonant transitions between bound quantum states, comprising at least one p-i-n structure with quantum dots on each side of the i-layer defining a quantum dot region, and potential barriers to separate this quantum dot region from the conduction p and n regions.

According to another aspect, the invention concerns a quantum thermoelectric converter for the environmental heat into electric energy comprising a longitudinal quantum heat converter with thermal injection of electrons, and a quantum photo-electric converter for converting a coherent electromagnetic energy into electric energy by quasi-resonant transitions between bound quantum states, comprising at least one p-i-n structure with quantum dots on each side of the i-layer defining a quantum dot region, and potential barriers to separate this quantum dot region from the conduction p and n regions.

According to another aspect, the invention concerns a quantum thermoelectric converter for the environmental heat into electric energy comprising a longitudinal quantum heat converter comprising at least one n-i-p-n structure with quantum dots on the two sides of the i-layer, a metal front electrode and a rear electrode, both electrodes forming an active cavity with the n-i-p-n structure in-between, a heat absorber in thermal contact with the metal front electrode, and an external mirror defining a transmission output cavity with the rear electrode, and a quantum photo-electric converter for converting a coherent electromagnetic energy into electric energy by quasi-resonant transitions between bound quantum states, as a super lattice of p-i-n diodes with quantum dots at the interfaces of the i-layer and separation barriers of the quantum dot region from the conduction p and n regions.

According to another aspect, the invention concerns a power supply comprising a heat converter according to any of the preceding aspects.

According to another aspect, the invention concerns a generator comprising a heat converter according to any of the preceding aspects.

According to another aspect, the invention concerns an integrated circuit comprising a heat converter, power supply or generator according to any other preceding aspects.

According to another aspect, the invention also concerns a microchip comprising a heat converter, power supply, generator, or integrated circuit according to any preceding aspects.

### BRIEF DESCRIPTION OF THE DRAWINGS

Other features and advantages of the invention will appear upon reading the following description which refers to the annexed drawings in which:

FIGS. 1a and 1b represent a classical system for energy production by a liquid decay that is the same either for a monotonic decay as in 1a) or for a flow in two main steps as in 1b);

FIG. 2 represents a longitudinal quantum heat converter, based on an electron flow in two steps, a super radiant decay and a thermal excitation;

FIG. 3 is a representation of a symbol of the longitudinal quantum heat converter of FIG. 2;

FIG. 4 is a symbolic representation of a longitudinal quantum heat converter with thermal injection of electrons;

FIG. 5, is a symbolic representation of a longitudinal quantum heat converter with auto-injection;

FIG. 6 represents a quantum photo-electric converter;

FIG. 7 is a representation of a symbol of a quantum photo-electric converter of FIG. 6;

FIG. 8 is a symbolic representation of a quantum thermoelectric converter.

### DETAILED DESCRIPTION OF THE INVENTION

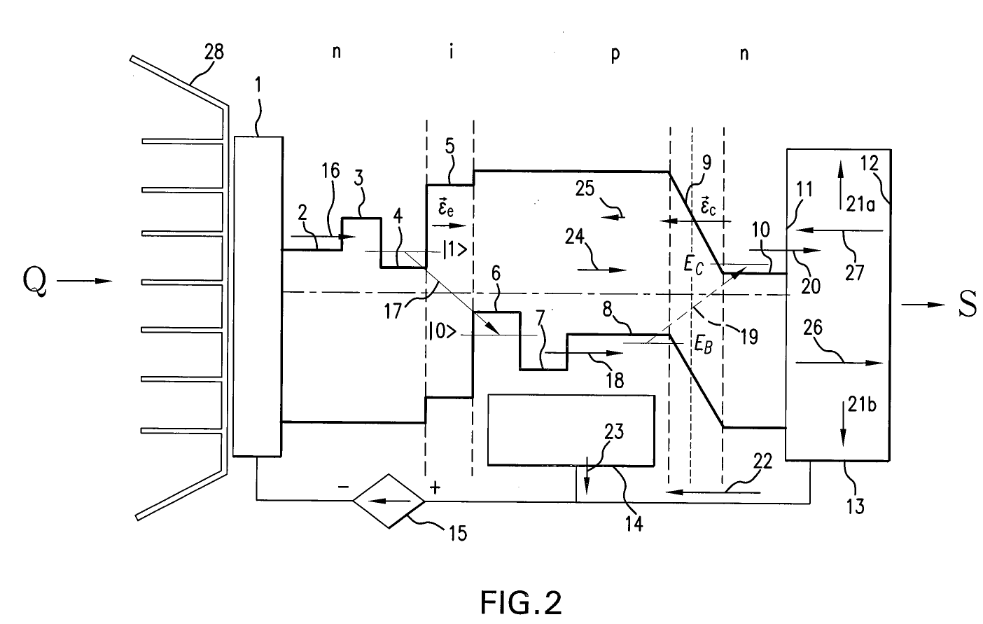

The present invention consists in a method and a semiconductor device for the coherent electromagnetic energy production on the account of the environment energy, by an electron transfer in two steps: (1) a super radiant decay, and (2) a thermal excitation. These method and semiconductor device will now be detailed only by way of non limiting examples in relation with FIGS. 2 to 8.

As a preliminary remark, it has been noticed within the scope of the present invention, that the processes of electron decay and excitation by heat absorption depend essentially on the coupling of the active electrons with the conduction electrons, the crystal vibrations and respectively the free modes of the electromagnetic field.

According to a first aspect, the present invention concerns a longitudinal quantum heat converter as represented in FIG. 2. The semiconductor device comprises an n-i-p-n structure 2-10, a double array of quantum dots 4 and 6 on the two sides of the thin i-layer 5 of the n-i emitter 2-5, a system of intermediate n and p layers separating the active quantum regions 4 and 6 from the n and respectively p regions 2 and 8 by potential barriers 3 and 7. It further comprises a metal front electrode 1, a heat absorber 28 in intimate or thermal contact with this electrode but not electrically in contact i.e. isolated one another. In fact, the heat absorber has to be as close as possible to the electrode to transmit to heat received from the environment to the internal semiconductor device. Furthermore, it comprises a semitransparent rear electrode 11 and an output semitransparent mirror 12 of the same transparency as the transparency of the rear electrode 11, by this forming with the rear electrode a total transmission Fabry-Perot resonator tuned with the electron quantum transition 17 frequency through the i-layer.

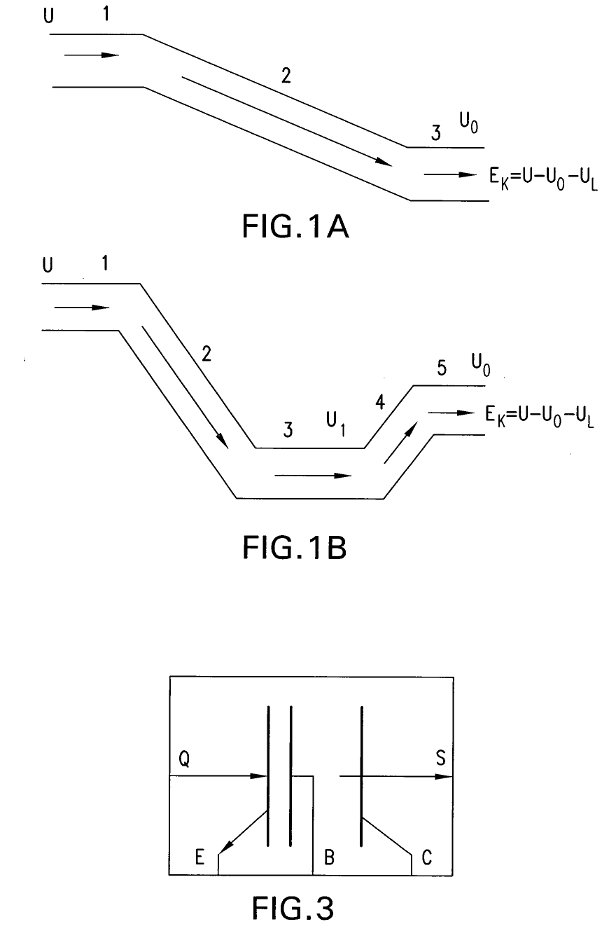

The operation of the quantum system is essentially based on the electron flow 17-18-19, somehow similar to the liquid flow in the classical system represented in FIG. 1b. Between the initial state |1>| of energy E₁ and the final state of energy Ec<E₁, an electron flow arises, while the mean energy E₁−E_{C} received by every of these electrons determines a diffusion current 20 at the beginning of the quasi neutral region of collector 10.

In a totally dissipative regime, the decaying energy E₁−E₀ of quantum transition 17 is converted into heat that is partially used for the electron excitation from the energy level E_{B} in the base region 8 to the energy level E_{C} in the collector region 10. The other part, remaining as an additional kinetic energy in comparison with the thermal energy, is finally dissipated in the collector region 10. That means that the current supply 15 provides only the energy loss in the electric circuit outside the active zones 3-9 to which is added the diffusion length from the collector region 10.

In a super radiant regime, when the coupling of an active electron with a mode of the electromagnetic field is sufficiently important in comparison with the dissipative couplings, an important part of the decaying energy is transferred to this mode, being radiated outside as usable energy. In this regime, the necessary energy for the electron excitation from E_{B} to E_{C} is taken from outside by the heat absorber 28, this heat propagating through the crystal lattice from the emitter metal electrode 1 to the collector metal terminal 13. A higher temperature of the emitter region 2 in comparison with that of the collector region 10 generates an additional internal field that increases the injected current I, the lower margin E_{C} of the conduction rising with the temperature T:

$$\begin{matrix}{E}_{c} = T ln \frac{{N}_{c} ( T )}{{N}_{D}} , \vert \\ where & ( 7 ) \\ {N}_{c} ( T ) = 2 {( \frac{\sqrt{{M}_{n} T / 2 π}}{ℏ} )}^{3} & ( 8 )\end{matrix}$$

is a coefficient depending on the electron effective mass Mₙ, N_{D} is the donor concentration, and T is in energy units.

The quantum transitions 17 become super radiant when the injected current I exceeds a threshold value

$${I}_{0} = \frac{1}{2} ɛ {N}_{e} {γ}_{\text{‖}} ( - {w}_{T} + \frac{{γ}_{⊥} {γ}_{F}}{{G}_{g}} ) , \qquad ( 9 )$$

depending on coupling coefficients

$$g = \frac{e}{ℏ} {r}_{01} , G = g \frac{ℏω}{2 ɛ𝒱} \qquad ( 10 )$$

in the cubic quantization volume V=Nₑ^{-3/2}, where r₀₁ is the electric dipole moment, ω is the frequency of the super radiant field, and Nₑ is the quantum dot superficial density. This current essentially depends on the dissipative coefficients of the electron system, i.e. the quasi-free electrons of the n-region, the quasi-free holes of the p-region, the crystal lattice vibrations, and the free electromagnetic field, expressed here in the following terms:

$$\begin{matrix}{γ}_{⊥} = & {λ}_{01} + {λ}_{10} + {λ}_{00} + {λ}_{11} & ( 11 a ) \\ {λ}_{\text{‖}} = & 2 ( {λ}_{01} + {λ}_{10} ) & ( 11 b ) \\ {w}_{T} = & - \frac{1 - {e}^{- {ℏω}_{0} / T}}{1 + {e}^{- {ℏω}_{0} / T}} , & ( 11 c )\end{matrix} \vert$$

and γF of the super radiant field, where ω₀≈ω is the quasi-resonant transition frequency.

In principle, a super radiant transition |1>→|0>|, i.e. from the initial state to the intermediate state, is assisted by several dissipative processes described by above formulas (4), (5) and (6).

According to the dissipative coefficients of formulas (4a and 4b), a quantum decay of energy ε₁₀ of an active electron is correlated with the probability rate λ₀₁^{F}| to the excitation of an electron in one of the two neighbouring conduction regions n and p, from an initial state |β> to a final state |α> with the same transition energy ε₁₀=ε_{αβ}. To diminish this coupling, the active quantum regions 4-6 are separated from the conduction regions 2 and 8 by the potential barriers 3 and respectively 7. However the dimensions of these barriers should not exceed the necessary values to enable the electron penetration by tunnelling. Actually, the super radiant transitions 17 are supplied by the incoming tunnelling current 16 and the outgoing tunnelling current 18. The maximum tunnelling current Iₜᵤ=PIₜₕ must be lager than the threshold current I₀, where P is the barrier penetrability and Iₜₕ=⅙·N·√(T/M) is the thermal current depending on the donor/acceptor concentration N, the electron/hole mass M, and temperature T.

Therefore, in this case, where the active quantum system is separated by potential barriers 3 and 7 from the conduction electrons, the process of interaction with the crystal vibrations described by formula (5) is dominant over the other processes that are much weaker. Thus the dissipation coefficients of formula (3) get the explicit forms

$$\begin{matrix}{λ}_{01} \approx {λ}_{01}^{B} = \frac{{E}_{e}^{2} {ɛ}_{10}^{5} {\overline{r}}_{01}^{2}}{{πℏ}^{6} {c}^{4} {υ}^{3} D} ( 1 + \frac{1}{{e}^{{ɛ}_{10} / T} - 1} ) & ( 12 a ) \\ {λ}_{10} \approx {λ}_{10}^{B} = \frac{{E}_{e}^{2} {ɛ}_{10}^{5} {\overline{r}}_{01}^{2}}{{πℏ}^{6} {c}^{4} {υ}^{3} D } \frac{1}{{e}^{{ɛ}_{10} / T} - 1} , & ( 12 b )\end{matrix}$$

where Eₑ=Mc² and

$$υ \approx \sqrt{\frac{E}{D}} \qquad ( 13 )$$

is the sound velocity that is a function the Young elasticity coefficient E and of the density D. In comparison with the Mösbauer effect where a large nuclear transition energy ε₁₀ leads to a wavelength of the order of the dimension of a crystal cell, that generally does not correspond to a phonon wavelength as an integer multiple of this dimension, our transition of rather small energy will always find a resonant phonon mode.

The base being much narrower than the electron diffusion length, the component 23, going out through the base terminal 14, of the diffusion current 18, is much lesser than the component 20-21a-21b-22 going out through the collector terminal 13. The currents 21a-21b represent the radial distribution of the collector current collected by the thin rear electrode 11, and going to the collector 13, preferably constructed as a cylindrical metal cladding of the output cavity defined between the mirrors 11 and 12.

On its trajectory 19 an electron takes energy from the internal electric field \vec{E}, which consequently decreases, while temperature of this region is also decreasing. To recover this energy of the internal electric field \vec{E}, a temperature increase is necessary, that is obtained by heat absorption.

Due to the coupling between the quantum transitions 17 and the travelling mode 24 propagating from the metal front electrode 1 to the rear thin electrode 11, a coherent electromagnetic field is generated, while a reminiscent counter propagating wave 25 appears. The quasi-resonant standing waves that could be generated in the cavity 1-11 by super radiance are mainly eliminated by the transmission cavity 11-12, which is much shorter and consequently has a rather large resonance. With a phase choice, the dynamics of this system is described by the Maxwell-Bloch-type equations for the component u(t) of the polarization amplitude S(t)=u(t)+iv(t), the population w(t) and the component G(t) of the electric field amplitude E(t)=F(t)+iG(t):

$$\begin{matrix}\frac{d}{d t} u ( t ) = - {γ}_{⊥} u ( t ) - g 𝒢 ( 0 , t ) w ( t ) \\ \frac{d}{d t} w ( t ) = - {γ}_{\text{‖}} [ w ( t ) - {w}_{T} ] + 2 ℐ ( t ) + ( 2 - 𝒯 ) g 𝒢 ( 0 , t ) u ( t ) \\ \frac{\partial }{\partial t} 𝒢 ( z , t ) {\vert}_{z = 0} - \sqrt{𝒯} c \frac{\partial }{\partial z} 𝒢 ( z , t ) {\vert}_{z = 0} = - {γ}_{F} 𝒢 ( z , t ) {\vert}_{z = 0} - G u ( t ) \\ \frac{\partial }{\partial t} 𝒢 ( z , t ) + c \frac{\partial }{\partial z} 𝒢 ( z , t ) = 0 , z > 0 ,\end{matrix} \qquad \begin{matrix}( 14 a ) \\ \\ ( 14 b ) \\ \\ ( 14 c ) \\ \\ ( 14 d )\end{matrix} \vert$$

where z=0 is the coordinate of an active quantum system that is much smaller than the cavity length,

$$ℐ ( t ) = \frac{I ( T )}{e {N}_{ρ}}$$

is the electron flow in this quantum system, and I is the transmission coefficient of the output optical system 11-12. When the injected current I(t)=eNₑI(t) exceeds the threshold value of injected current defined in formula (9), an inversion population is provided according to formula (14b). This population provides quantum transitions

$${ρ}_{10} ( t ) = \frac{1}{2} 𝒮 ( t ) {e}^{- iω t}$$

of polarization S(t)=u(t) according to formula (14a). These transitions generate a super radiant field according to formula (14c) that, according to formula (14d), further propagates to the output mirror 11.

Since the mirrors 11, 12 have equal transmission coefficients T₁, and form a resonant Fabry-Perot cavity, the electromagnetic wave 24 is totally transmitted outside, while the amplitudes 26 and 27 in this cavity are much larger, in a ratio 1/(√T₁) and respectively (√(1−T₁))/(√T₁). In this case, the transmission coefficient of the field from the active cavity 1-11 becomes equal to 1, the electromagnetic power generated in this cavity being then totally extracted. Thus, the super radiant field flow S, generated in this process, is the result of a competition between the matter-field coupling coefficients of formula (10) and the dissipative couplings coefficients of formula (11) with the terms defined in formulas (3) to (6).

FIG. 3 is a schematic representation of a longitudinal quantum heat converter as represented in FIG. 2. It represents a symbol of the semiconductor device with three electric terminals, E as emitter, B as base and C as collector, with a heat absorber Q and a coherent electromagnetic energy radiator S.

As above described in relation with the first aspect of the present invention, a heat flow is converted into coherent electromagnetic power in a longitudinal quantum heat converter. The operation of this device is essentially based on the injection of an electron current at a much lower power than the generated optical power that comes from the heat absorption. This current may be obtained from an external circuit, as those described in the co-pending application Ser No “B-16583” entitled “quantum injection system”, which is enclosed herewith by way of reference.

A first advantageous variant of the longitudinal quantum heat converter described in relation with FIG. 2, is based on the fact that such a polarization current of the semiconductor device may be obtained as a thermoelectric effect arising in the device under a sufficient large difference of temperature between the two n-regions of the emitter and of the collector.

For that purpose, this first variant of longitudinal quantum heat converter concerns a system of two quantum heat converters with longitudinal radiation converting a heat flow, between a heat absorber placed at a higher temperature and a heat radiator situated at a lower temperature, in coherent electromagnetic power. The electron current generated by thermo-electric effect in one device is looped with the other device, the thermoelectric voltages generated by the two devices being summed-up in the serial electric circuit of the two devices. The resulting radiation direction of the device is the same as the heat flow direction.

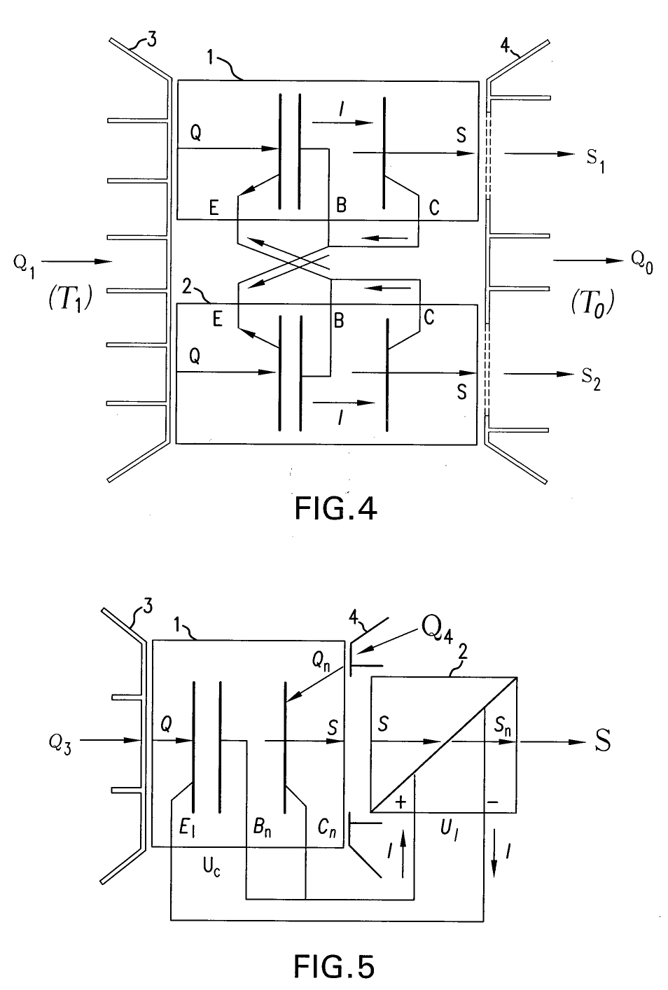

FIG. 4 represents symbolically a longitudinal quantum heat converter with thermal injection of electrons. More specifically, this first variant consists in a system of two longitudinal quantum heat converters 1 and 2 of the type represented in FIG. 3, electrically connected in a ring, one converter being the load of the other converter and conversely. The two emitters E₁ and E₂ are in intimate or thermal contact with a heat absorber 3 being at a higher temperature, and the two collectors C₁ and C₂ are in intimate or thermal contact with a heat radiator 4 being at a lower temperature, while the two output windows 5 and 6 radiate two parallel electromagnetic beams S₁ and S₂ in the direction of the heat flow Q₀. Advantageously, in a ring of more than two longitudinal quantum heat converters, the total series resistance being n times larger than the series resistance of one longitudinal quantum heat converter, the stability of the device may be improved.

Preferably as the heat converter of FIG. 2, each longitudinal quantum heat converter 1 and 2 is a heat converter comprising at least one super radiant n-i-p-n transistor with quantum dots on the two sides of the i-layer and separation barriers of the quantum dot regions from the conduction regions n and p.

Referring back to FIG. 4, the two longitudinal quantum heat converters 1 and 2 are placed in a thermal field between temperature T₁ of the heat absorber 3 and temperature T₀ of the heat radiator 4. Corresponding to this temperature difference, the following internal voltage is generated:

$$U = \frac{{T}_{1}}{e} ln \frac{{N}_{c} ( {T}_{1} )}{{N}_{D}} - \frac{{T}_{0}}{e} ln \frac{{N}_{c} ( {T}_{0} )}{{N}_{D}} \vert \\ where$$

$${N}_{c} ( T ) = 2 {( \frac{\sqrt{{M}_{n} T / 2 π}}{ℏ} )}^{3}$$

is a coefficient depending on temperature T expressed in energy units, the effective mass Mₙ of the electron in the n region of the emitter/collector of the device, and the donor concentration N_{D} that is supposed to be the same in the emitter and in the collector.

Under this voltage and while a heat flow Q₁ is absorbed at a higher temperature T₁, and a lesser heat flow Q₀ is radiated at a lower temperature T₀, a thermoelectric current I is generated in the device. When this current exceeds a certain threshold value I₀, the super radiant electromagnetic energy flows S₁ and S₂ are generated by the longitudinal quantum heat converters 1 and respectively 2.

As above described in relation with the first aspect of the present invention, a heat absorbed from the environment is partially converted into super radiant power when an electron current is injected in the semiconductor device, the absorbed electric power being much lesser than the super radiant power. When using a quantum injection system as described in the co-pending application Ser No “B-16583” entitled “quantum injection system”, which is enclosed herewith by way of reference, a coherent electromagnetic energy flow can be transformed into an injected current at a voltage that can me matched with the polarization voltage of the longitudinal quantum heat converter.

For that purpose, a second advantageous variant of longitudinal quantum heat converter concerns a super radiant system composed of a longitudinal quantum heat converter as described in relation with FIG. 2 and a quantum injection system with the same proper voltage as disclosed in the above mentioned co-pending application Ser No. “B-16583”. Thus while the heat absorbed by the system is converted into coherent electromagnetic energy, a part of this energy is used for providing the necessary injection current for the device operation.

FIG. 5 is a symbolic representation of a longitudinal quantum heat converter with auto injection. It consists in a system composed of a longitudinal quantum heat converter 1, and a quantum injection system 2. The necessary polarization current is provided by converting into electric power a part of the radiated electromagnetic power.

Getting now into details of FIG. 5, the longitudinal quantum heat converter 1 with its thermal terminal Q being in intimate contact with the heat absorber 3, is optically coupled with the quantum injection system 2. Additionally its thermal terminal Qₙ may be in intimate contact with another heat absorber not shown. The polarization voltage U_{C} of the quantum heat converter 1 and the polarization voltage U_{I} of the quantum heat injector 2 being matched, when these two devices are electrically coupled the operation injection current I is provided. While an electromagnetic power flow is generated by the device 1 on the account of the heat flows Q₃ and potentially Q₄ provided by the heat absorbers 3 and respectively the one in contact with the terminal Qₙ, a little part of this power is transformed into electric power by the device 2, the most part S remaining available as an useful power.

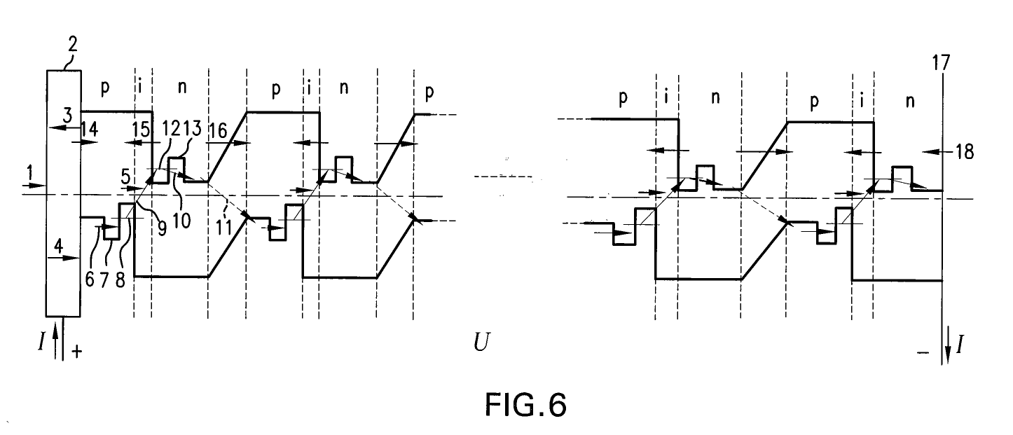

As already seen with the different variants of quantum heat converters, a coherent electromagnetic field is generated by absorbing heat from the environment. With an active Fabry-Perot transmitter or a quantum injection device as detailed in the co-pending application C Ser No “B-16583” entitled “Quantum injection system”, a little part of the power of a coherent electromagnetic beam that is crossing the device is converted into electric power. According to a second aspect, the present invention concerns a semiconductor device for the total conversion of a coherent electromagnetic energy flow into electric power represented in FIG. 6.

For that purpose, the second aspect concerns a semiconductor device transforming the energy of a coherent electromagnetic beam into electric energy, as an active Fabry-Perot resonator including a super lattice of p-i-n diodes with resonant quantum injection of electrons between quantum dot arrays situated on the two sides of the i-region. While the electrons are injected from the anode quantum dots to the cathode quantum dots by resonant absorption, these electrons undertake a dissipative decay in the cathode conduction region, further recombining with the holes diffusing from the anode p-region of the following diode that is directly polarized, or being carried to the rear electrode. The device also includes a front electrode system as a resonant Fabry-Perot cavity with total transmission for capturing the incident beam, and a rear metal electrode. Indeed the passive Fabry-Perot resonator, being perfectly tuned for the frequency of the input light behaves as a total transmitter of this light to the active semiconductor region.

FIG. 6 represents a quantum photo-electric converter according to the second aspect of the present invention. An input coherent electromagnetic wave 1 with the amplitude ε₁ is coupled to the passive Fabry-Perot resonator 2 where the counter-propagating waves 3 and 4 are generated, while a wave 5 with an amplitude ε₅≈ε₁ is injected in the active zone, inducing quasi-resonant transitions 9 between the energy levels 8 and 12. From the higher levels 12, the electrons undertake a dissipative tunnelling 10 through the separation barriers 13 to the n conduction regions, by direct polarization of the n-p junctions undertaking an injection 11 from a p-i-n diode to the following p-i-n diode. By dissipative tunnelling processes 6 the electrons penetrate the barriers 7 to the lower levels 8 of the optical transitions 9. By the quasi-resonant absorption of the field in the active region between the passive Fabry-Perot resonator 2 and the electrode 17, an electron current I is generated at a voltage U determined by the variations of the internal fields 14, 15, 16, . . . 18.

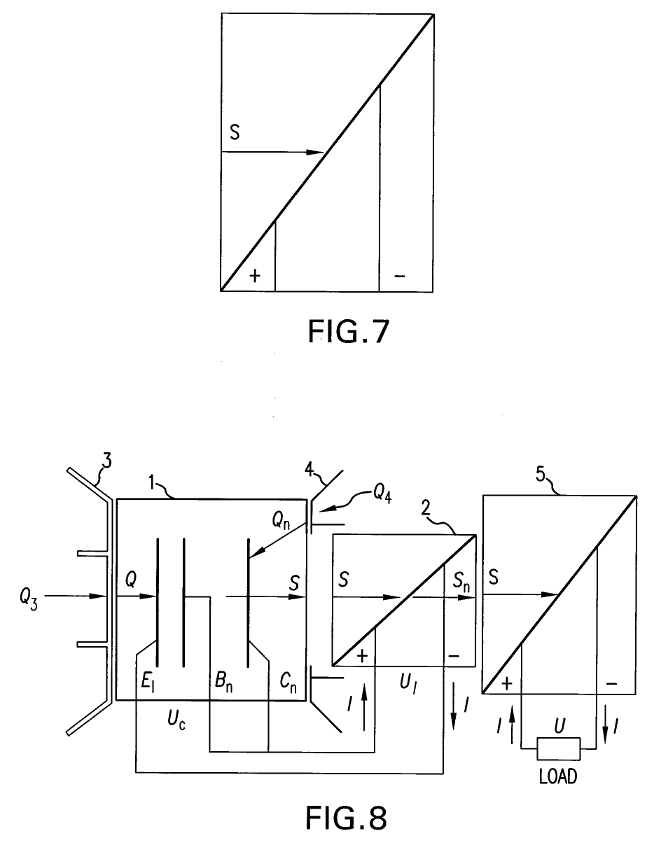

FIG. 7 represents a symbol of a quantum photo-electric converter of FIG. 6, with an optical terminal S for the input electromagnetic power and two electric terminals +, − for the output electric power.

Advantageously in order to obtain a constant current flowing through the whole structure with several p-i-n semiconductor devices, the dipole moment d₁ in the first structure p-i-n determines the current I by the radiation of S₁ coming on the first junction 9. Then the radiation of S₂ which is lower than S₁ arrives at the second junction and the dipole moment should therefore be chosen to imply the same current I. For having the same current, the dipole moment in the second structure has to be increased since the electromagnetic field S decreases. For that purpose, either the width of the intermediate region may be reduced, or the potential barrier of each structure p-i-n may be reduced.

A third aspect of the present invention concerns an electric supply taking energy from the environment, composed of a longitudinal quantum heat converter with auto injection as described in relation with FIG. 5 and a quantum photo-electric converter as described in relation with FIGS. 6 and 7. The environmental heat is converted into electric energy in two steps: (1) a heat conversion into coherent electromagnetic energy, and (2) a coherent electromagnetic energy conversion into electric energy.

FIG. 8 represents such a quantum thermoelectric converter. A heat flow Q₃+Q₄ absorbed from the environment is partially converted into an electric power U_{I}·I_{I}, necessary for the device operation, the remaining part being converted into a usable electric power U*I.

The longitudinal quantum heat converter 1 with the polarization voltage U_{C} is polarized with the necessary operation current I_{I} by the quantum injection system 2 with approximately the same polarization voltage U_{I}≈U_{C}. The heat flows Q₃ and Q₄ provided by the heat absorbers 3 and 4 are converted by the converter 1 into an electromagnetic energy flow that is partially converted by the injection system 2 into the necessary polarization power U_{I}·I_{I}. The remaining electromagnetic energy flow, after crossing the injection system 2, is converted by the quantum photo-electric converter 5 into electric power, providing an electron current I at the characteristic voltage U to a LOAD.

It is to note that preferably the load voltage is not used for the current injection in the quantum heat converter because the load has first to be separated from the generator and second it may be different according to the application and as such cannot be used trustfully for supplying the converter. For that reason, either auto injection from the Fabry-Perot cavity or temperature difference may be used to provide the current supply.

Having described the invention with regard to certain specific embodiments, it is to be understood that these embodiments are not meant as limitations of the invention. Indeed, various modifications, adaptations and/or combination between embodiments may become apparent to those skilled in the art without departing from the scope of the annexed claims.

For instance, at the end of the active cavity or laser cavity, the last junction p-n could be alternatively replaced either with an n semiconductor or directly with a metal plate which behaves like a n semiconductor.

According to an advantageous embodiment applicable to any of the previous aspects of the invention, it is provided that the resonant cavity located between both front and rear electrodes has an overall length equal to an integer number of times of the wavelength of the super radiant electromagnetic field propagating in the direction of the electron flow through n-i-p-n structures. It is also provided that advantageously each i layer of the n-i-p-n structures are spaced from the front electrode, and preferably also from the rear one, by an integer number of the wavelength of the super radiant electromagnetic field.

Otherwise the above description refers only to n-i-p-n semiconductor structures; nevertheless, it is understandable that p-i-n-p semiconductor structures might be used even if such structures present many defects notably in terms of mobility of electrons in the p-regions which is too slow and in terms of the overall size of the semiconductor structure since the p-regions have to be much larger in comparison with the n-regions of an n-i-p-n structure.

1. A method for producing in a semiconductor device coherent electromagnetic energy on account of environmental heat by an electron flow between an initial potential and a lower final potential, the method comprising the steps of:
(a) providing a super radiant quantum decay of electrons to an intermediate potential that is much lower than both an initial potential and a final potential; and
(b) generating a thermal excitation of electrons from the intermediate potential to the final potential by taking energy from an internal field region of the semiconductor device and recovering this energy by heat absorption from the environment.

2. The method of claim 1, further comprising an additional step for extracting the electromagnetic energy generated inside the semiconductor device through an output resonant cavity with total transmission.

3. The method of claim 2, where the super radiant quantum decay is coupled to an electromagnetic field mode propagating in the same direction as electron flow through the semiconductor device.

4. The method of claim 3, wherein a current generated during the thermal excitation step by a thermoelectric effect is injected in the semiconductor device.

5. A semiconductor device for the heat conversion into coherent electromagnetic energy according to claim 3.

6. A longitudinal quantum heat converter for environmental heat conversion into coherent electromagnetic energy, comprising:
(a) at least one n-i-p-n structure with quantum dots on both sides of the i-layer;
(b) a metal front electrode and a rear electrode, both electrodes forming an active cavity with the n-i-p-n structure in-between;
(c) a heat absorber in thermal contact with the metal front electrode; and
(d) an external mirror defining a transmission output cavity with the rear electrode.

7. The converter of claim 6, wherein the n-i-p-n structure with quantum dots forms a super radiant transistor, the p-region being much narrower than the electron diffusion length.

8. The converter of claim 6, wherein the n-i-p-n structure with quantum dots forms a super radiant transistor with an n-emitter, a p-base and an n-collector.

9. The converter of claim 6, wherein the first n region and the p region of the n-i-p-n structure form two conduction regions, and wherein quantum dots together with the i-layer form an active quantum dot region that is separated from the two conduction regions by potential barriers.

10. The converter of claim 9, wherein the potential barriers have rather high penetrabilities to enable quantum tunnelling between the active quantum dot region and the conduction regions.

11. The converter of claim 6, wherein the rear electrode and the external mirror are semitransparent with the same coefficient of transparency.

12. The converter of claim 9, wherein the active quantum dot region has two different energy levels defining a super radiant transition frequency, and wherein the rear semitransparent electrode forms with the front metal electrode a Fabry-Perot cavity tuned with the super radiant transition frequency.

13. The converter of claim 6, wherein the external mirror has a transmission coefficient equal to the transmission coefficient of the rear electrode forming with the rear electrode a total transmission resonant cavity.

14. The converter of claim 6, wherein the active cavity comprises several n-i-p-n structures connected in series.

15. A semiconductor device for producing a coherent electromagnetic energy on the account of the environmental heat, comprising at least one n-i-p-n structure including an active electron system separated by potential barriers from a sea of conduction electrons, a heat absorber to supply the necessary thermal energy to the active electron system, and an output Fabry-Perot cavity with total transmission for extracting the coherent electromagnetic energy from the n-i-p-n structure.

16. A longitudinal quantum heat converter for environmental heat conversion into coherent electromagnetic energy, comprising:
(a) at least one n-i-p-n structure including a first n-i-p junction and a second p-n junction;
(b) a heat absorber in thermal contact with a metal front electrode of the n-i-p-n structure; and
(c) an external mirror defining a total transmission output cavity with a rear electrode of the n-i-p-n structure.

17. The converter of claim 16, wherein electrons crossing the first n-i-p junction by super radiant quantum decay, are injected by transistor effect in the second p-n junction.

18. A longitudinal quantum heat converter for environmental heat conversion into coherent electromagnetic energy, comprising:
(a) an active cavity with at least one n-i-p-n structure inside;
(b) a heat absorber in thermal contact with the active cavity; and
(c) a transmission output cavity for extracting electromagnetic energy from the active cavity.

19. A quantum heat converter with thermal injection of electrons composed of two longitudinal quantum heat converters of claim 8, electrically connected in a ring, where one of the two longitudinal quantum heat converters is the load of the other and conversely, and optically paralleled, with the two n-emitters in thermal contact with a common heat absorber at a higher temperature, and the two n-collectors in thermal contact with a heat radiator at a lower temperature, and emitting two parallel electromagnetic beams by heat absorption from the environment.

20. A quantum heat converter with auto injection for environmental heat conversion into coherent electromagnetic energy, comprising one longitudinal quantum heat converter of claim 6, optically and electrically coupled with a quantum injection system wherein the coherent electromagnetic energy is partially used for generating injection current that is necessary to the operation of the longitudinal quantum heat converter.

21. A quantum photo-electric converter for converting a coherent electromagnetic energy into electric energy by quasi-resonant transitions between bound quantum states, comprising:
(a) at least one p-i-n structure with quantum dots on each side of the i-layer defining a quantum dot region; and
(b) potential barriers to separate this quantum dot region from the conduction p and n regions.

22. The quantum photo-electric converter of claim 21, further comprising a super lattice of p-i-n structures.

23. The quantum photo-electric converter of claim 22, wherein the super-lattice of p-i-n structures is an active medium of a Fabry-Perot resonator.

24. The quantum photo-electric converter of claim 22, wherein a dipole moment of each p-i-n structure is increased compared to a dipole moment of the previous p-i-n structure so that the current flowing through all the p-i-n structures is constant.

25. A method for converting environmental heat into electric energy in two steps, which are:
(1) a conversion of heat into coherent electromagnetic energy by a longitudinal quantum heat converter with auto injection; and
(2) a conversion of a coherent electromagnetic energy into electric energy by a quantum photo-electric converter.

26. A quantum thermoelectric converter for converting environmental heat into electric energy, comprising:
(a) the longitudinal quantum heat converter with auto injection of claim 20; and
(b) a quantum photo-electric converter for converting a coherent electromagnetic energy into electric energy by quasi-resonant transitions between bound quantum states, the quantum photo-electric converter comprising
i. at least one p-i-n structure with quantum dots on each side of the i-layer defining a quantum dot region; and
ii. potential barriers to separate the quantum dot region from the conduction p and n regions.

27. A quantum thermoelectric converter for converting environmental heat into electric energy, comprising:
(a) the longitudinal quantum heat converter with thermal injection of electrons of claim 19; and
(b) a quantum photo-electric converter for converting a coherent electromagnetic energy into electric energy by quasi-resonant transitions between bound quantum states, the quantum photo-electric converter comprising
i. at least one p-i-n structure with quantum dots on each side of the i-layer defining a quantum dot region; and
ii. potential barriers to separate the quantum dot region from the conduction p and n regions.

28. A quantum thermoelectric converter for the environmental heat into electric energy, comprising:
(a) a longitudinal quantum heat converter comprising
i. at least one n-i-p-n structure with quantum dots on both sides of the i-layer;
ii. a metal front electrode and a rear electrode, both electrodes forming an active cavity with the n-i-p-n structure in-between;
iii. a heat absorber in thermal contact with the metal front electrode; and
iv. an external mirror defining a transmission output cavity with the rear electrode; and
(b) a quantum photo-electric converter for converting a coherent electromagnetic energy into electric energy by quasi-resonant transitions between bound quantum states, wherein the quantum photo-electric converter comprises a super lattice of p-i-n diodes with quantum dots at the interfaces of the i-layer and separation barriers of the quantum dot region from the conduction p and n regions.

29. A power supply comprising a longitudinal quantum heat converter according to claim 6.

30. A power supply comprising a quantum thermoelectric converter according to claim 28.

31. A generator comprising a longitudinal quantum heat converter according to claim 6.

32. A generator comprising a quantum thermoelectric converter according to claim 26.

33. A generator comprising a quantum thermoelectric converter according to claim 27.

34. A generator comprising a quantum thermoelectric converter according to claim 28.

35. An integrated circuit comprising a longitudinal quantum heat converter according to claim 6.

36. An integrated circuit comprising a quantum thermoelectric converter according to claim 26.

37. A microchip comprising a longitudinal quantum heat converter according to claim 6.

38. A microchip comprising a quantum thermoelectric converter according to claim 26.

39. The converter of claim 14, wherein a super radiant electromagnetic field propagates in the same direction as the electron flow through the n-i-p-n structures, and wherein each i-layer of the n-i-p-n structures are spaced from the front electrode by an integer number of the wavelength of the super radiant electromagnetic field.

40. A method and semiconductor n-i-p-n device according to claim 5, absorbing energy from the environment in the internal filed of the p-n semiconductor junction that becomes colder by transferring its field energy to an electron flow that is injected by thermoelectric effect in the super radiant p-i-n junction.
